(19) United States
(12) Patent Application Publication
(10) Pub. No.: US 2025/0233586 A1
(43) Pub. Date: Jul. 17, 2025

(54) SWITCH DEVICE AND TESTING DEVICE

(71) Applicant: ADVANTEST CORPORATION, Tokyo (JP)

(72) Inventor: Takahiro TSUSHIMA, Miyagi (JP)

(21) Appl. No.: 19/170,024

(22) Filed: Apr. 3, 2025

Related U.S. Application Data
(63) Continuation of application No. PCT/JP2023/001065, filed on Jan. 16, 2023.

(51) Int. Cl. H03K 17/687; G01R 31/28

(52) U.S. Cl. CPC H03K 17/6871; G01R 31/2884

(57) ABSTRACT

A switch device comprising: a plurality of routing circuits each configured to switch whether to electrically connect between a first port and each of a plurality of second ports; and a plurality of clamp circuits, wherein each of the plurality of routing circuits comprises: a connection switching circuit configured to switch whether to electrically connect between the first port and a corresponding second port among the plurality of second ports; and at least one ground switching circuit configured to switch whether to ground a wiring between the first port and the corresponding second port among the plurality of second ports, and wherein each of the plurality of clamp circuits is electrically connected between a node on a wiring between the corresponding second port among the plurality of second ports and the connection switching circuit of a corresponding routing circuit among the plurality of routing circuits, and a reference potential.

### CROSS-REFERENCE TO RELATED APPLICATION

This application is a continuation of International Application No. PCT/JP2023/001065 filed on Jan. 16, 2023, the contents of which are hereby incorporated by reference in their entirety.

### TECHNICAL FIELD

The present invention relates to a switch device and a testing device.

### RELATED ART

In Patent Document 1, it is described that “in other words, the passive switchable power splitter 20 includes a passive splitter 21 including N+1 equivalent resistors R₁ to R_{N+1}, and N single pole single throw (SPST) switches 22₂ to 22_{N+1} connected between equivalent resistors R₂ to R_{N+1} and output ports P₂ to P_{N+1}.” (paragraph 0022), and “the SPST switches 22₂ to 22_{N+1} used in FIG. 3 do not depend on whether each port is transmitting (i.e., active) or non-transmitting (i.e., inactive), or in other words, not depending on the setting state. The switches are absorptive in that they ideally provide perfect impedance matching for both of those ports. Thus, the passive splitter 20 shown in FIG. 3 functions as in the normal case (all its ports are impedance matched), while all of the output ports P₂ to P_{N+1} can be individually selected to transmit or not transmit” (paragraph 0023).

In Patent Document 2, it is described that “in this semiconductor switch circuit, first and second unit switches 201, 202 are connected in series between a first individual terminal P1 and a second individual terminal P2, and, a SPDT switch circuit is configured by connecting a mutual connection point of these first and second unit switches 201, 202 to a common terminal PC” (paragraph 0002) and “further, in this conventional circuit, in place of the so-called shunt switch, in order to strengthen the ESD protection, the diodes connected with each other in the reverse direction (Back-to-Back) are set as a minimum unit, and an ESD protection element 203 in which ten of such diodes are connected in series is provided between the common terminal PC and the ground.”

In Patent Document 3, it is described that “in FIG. 1, the high-frequency switch circuit has a reception terminal (output terminal) 1, a transmission terminal (input terminal) 2, and an antenna terminal (input/output terminal) 3” (paragraph 0020), “a reception-side transfer circuit 11 is disposed between the reception terminal 1 and the antenna terminal 3, and a transmission-side transfer circuit 12 is disposed between the transmission terminal 2 and the antenna terminal 3” (paragraph 0021), and “the high-frequency switch circuit further includes a receiving shunt circuit 13a disposed between the receiving terminal 1 and the ground 4, a transmitting shunt circuit 14a disposed between the transmitting terminal 2 and the ground 4, and an ESD protection circuit 15 disposed between the antenna terminal 3 and the ground 4” (paragraph 0028).

In Patent Document 4, it is described that “modern electrical measurements have become increasingly sensitive to electrostatic discharge (ESD) and electrical overstress (EOS)” (paragraph 0002), and “the diode array is composed of a plurality of series stacks distributed along the length of the transmission line. By using a series stack of diodes, the desired clamping voltage is obtained without the need for an externally applied bias voltage” (paragraph 0010).

### CITATION LIST

### Patent Document

Patent Document 1: Japanese Patent No. 6117950
Patent Document 2: Japanese Patent Application Publication No. 2013-26982
Patent Document 3: Japanese Patent Application Publication No. 2009-124653
Patent Document 4: Japanese Patent Application Publication No. H10-65474

### GENERAL DISCLOSURE

In a first aspect of the present invention, provided is a switch device comprising: a plurality of routing circuits each configured to switch whether to electrically connect between a first port and each of a plurality of second ports; and a plurality of clamp circuits, wherein each of the plurality of routing circuits comprises: a connection switching circuit configured to switch whether to electrically connect between the first port and a corresponding second port among the plurality of second ports; and at least one ground switching circuit configured to switch whether to ground a wiring between the first port and the corresponding second port among the plurality of second ports, and wherein each of the plurality of clamp circuits is electrically connected between a node on a wiring between the corresponding second port among the plurality of second ports and the connection switching circuit of a corresponding routing circuit among the plurality of routing circuits, and a reference potential.

In the above switch device, each of the plurality of clamp circuits may be electrically connected between nodes on wirings between each of the plurality of second ports and the corresponding routing circuit among the plurality of routing circuits, and a reference potential.

In any switch device described above, the at least one ground switching circuit of each of the plurality of routing circuits may be configured to ground the wiring between the first port and the corresponding second port among the plurality of second ports when the first port and the corresponding second port among the plurality of second ports are not electrically connected.

In any switch device described above, each of the plurality of clamp circuits may be configured to restrict a potential difference between the corresponding node and the ground to greater than a maximum value and less than twice the maximum value of a potential difference between an output signal to be output from the second ports and the ground.

In any switch device described above, each of the plurality of clamp circuits may comprise: a plurality of first diodes that are forward connected in series between the corresponding node and the reference potential.

In any switch device described above, each of the plurality of clamp circuits may comprise a plurality of second diodes that are backward connected in series between the corresponding node and the reference potential.

In any switch device described above, each of the plurality of routing circuits may comprise at least one variable resistor circuit configured to make a connection resistance value variable when the first port and the corresponding second port among the plurality of second ports are electrically connected.

In any switch device described above, in each of the plurality of routing circuits, all ground switching circuits among the at least one ground switching circuit may be connected nearer to the first port than a variable resistor circuit that is connected nearest to the second ports among the at least one variable resistor circuit in the wiring between the first port and the corresponding second port among the plurality of second ports.

In any switch device described above, the plurality of second ports may be connected to one or more devices under test, and the first port may be connected to a testing circuit configured to test the one or more devices under test.

In a second aspect of the present invention, provided is a testing device comprising: any switch device described above; and the testing circuit.

The summary clause does not necessarily describe all necessary features of the embodiments of the present invention. The present invention may also be a sub-combination of the features described above.

### BRIEF DESCRIPTION OF THE DRAWINGS

FIG. 1 illustrates a configuration of a testing device 1 according to the present embodiment.

FIG. 2 illustrates a circuit configuration of a switch device 200 as a comparative example.

FIG. 3 illustrates a state of the switch device 200 in which ports P1 and P2-1 are connected and ports P1 and P2-2 are disconnected.

FIG. 4 illustrates an example of a circuit configuration of a through switch 422 and a shunt switch 424 as a comparative example.

FIG. 5 illustrates an example of a circuit configuration of a switch device 120 according to the present embodiment.

FIG. 6 illustrates an example of a circuit configuration of a clamp circuit 550 according to the present embodiment.

FIG. 7 illustrates an example of a circuit configuration of a through switch 222 and a shunt switch 224 according to the present embodiment.

FIG. 8 illustrates an example of a circuit configuration of a switch device 800 according to a modification.

### DESCRIPTION OF EXEMPLARY EMBODIMENTS

Hereinafter, the present invention will be described through embodiments of the invention, but the following embodiments do not limit the invention according to the claims. In addition, not all combinations of features described in the embodiments are essential to the solution of the invention.

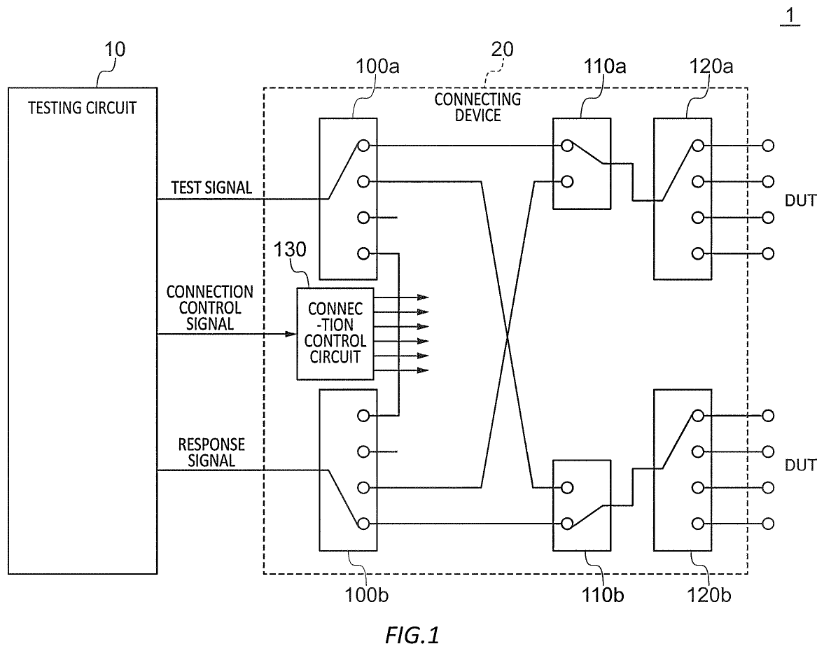

FIG. 1 illustrates a configuration of a testing device 1 according to the present embodiment. The testing device 1 includes a testing circuit 10 and a connecting device 20.

The testing circuit 10 is connected to one or more devices under test (DUTs) via the connecting device 20, and is configured to test the one or more DUTs. The testing circuit 10 may include various circuits for determining a quality of a DUT by transmitting and receiving a signal to/from the DUT, including at least one of a pattern generator for generating a test pattern, a timing generator for generating a timing, a waveform shaper for shaping the test pattern by using the timing generated by the timing generator to output a test signal, a driver circuit for amplifying the test signal to output it to the DUT, a comparator for comparing a response signal from the DUT to a target value, or a determiner for determining the quality of the DUT by using the comparison result by the comparator.

In addition, the testing circuit 10 may supply the connecting device 20 with a connection control signal for controlling switching between terminals of the DUTs connected to the testing circuit 10 in accordance with tests to be executed. The testing device 1 may include a testing controller configured to control a test on each DUT by the testing circuit 10, and, instead of the testing circuit 10, the testing controller may supply the connecting device 20 with the connection control signal.

The connecting device 20 is connected to the testing circuit 10 and the one or more DUTs, and is configured to switch the connections between the testing circuit 10 and the one or more DUTs in response to the connection control signal received from the testing circuit 10. In the present drawing, a configuration of switching the connections between an output terminal of the test signal and an input terminal of the response signal of the testing circuit 10, and eight terminals of the one or more DUTs is illustrated in the connecting device 20. It will be noted that, as used herein, unless explicitly specified otherwise, the term “connection” means an “electrical connection”, and, without being limited to a direct electrical connection between components, means that it may be an indirect electrical connection with another component connected therebetween.

The connecting device 20 includes switch devices 100a to 100b, switch devices 110a to 110b, switch devices 120a to 120b, and a connection control circuit 130. The switch devices 100a to 100b (also referred to as “switch device(s) 100”) are Single Pole Quadruple Throw (SP4T) switches. The switch device 100a is configured to switch to which of four ports the output terminal of the testing circuit 10 (the output terminal of the test signal) is connected. The switch device 100b is configured to switch to which of four ports the input terminal of the testing circuit 10 (the input terminal of the response signal) is connected. Here, in the figure, the fourth port from the top on the right side of the switch device 100a and the first port from the top on the right side of the switch device 100b are electrically connected through a wiring. This wiring functions as a loopback path for looping the test signal from the testing circuit 10 in the connecting device 20 back to the testing circuit 10.

The switch devices 110a to 110b (also referred to as “switch device(s) 110”) are Single Pole Double Throw (SPDT) switches. The switch device 110a is configured to switch which of the switch device 100a or the switch device 100b is connected to the switch device 120a. The switch device 110b is configured to switch which of the switch device 100a or the switch device 100b is connected to the switch device 120b.

The switch devices 120a to 120b (also referred to as “switch device(s) 120”) are Single Pole Quadruple Throw (SP4T) switches. The switch devices 120 are configured to switch whether to connect each of four terminals of the DUTs on the right side of the switch device 120 in the figure to the switch device 110. The switch devices 120 may connect any number of the terminals (in the present drawing, one, two, three, or four terminals) among the four terminals of the DUTs on the right side of the switch device 120 to the switch device 110. In this manner, the switch devices 120 also function as a power splitter for connecting two or more terminals of the DUTs to the switch device 110.

The connection control circuit 130 is configured to switch the connections of the switch devices in the connecting device 20 such as the switch devices 100a to 100b, the switch devices 110a to 110b, and the switch devices 120a to 120b as specified by the connection control signal received from the testing circuit 10. The example of the present drawing shows that the connection control circuit 130 controls each switch device to transmit the test signal from the testing circuit 10 to a terminal of a DUT connected to the first port from the top on the right side of the switch device 120a and transmit a response signal received from a terminal of a DUT connected to the first port from the top on the right side of the switch device 120b to the testing circuit 10.

The connecting device 20 described above is configured by a combination of two switch devices 100, two switch devices 110, and two switch devices 120. The connection form of one or more switch devices provided in the connecting device 20, and the number of ports of each switch device or the like may be changed arbitrarily in accordance with the usage form of the testing device 1.

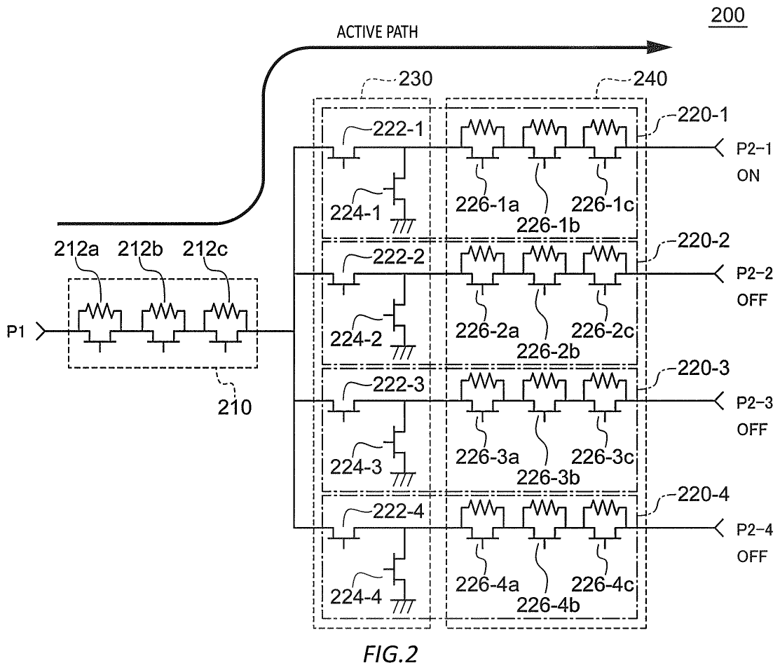

FIG. 2 illustrates a circuit configuration of a switch device 200 as a comparative example. The switch device 200 can be used as the switch device 120 in FIG. 1. The switch device 200 is configured to switch whether to electrically connect a first port (port P1) and each of a plurality of second ports (ports P2-1 to P2-4). In FIG. 1, the port P1 of the switch device 200 is connected to the testing circuit 10 via the switch devices 110 and the switch devices 100, and the plurality of ports P2 of the switch device 200 are connected to the one or more DUTs. The switch device 200 may be achieved by using a semiconductor element such as a MOSFET formed on a substrate, or may be achieved by using a Silicon-on-Insulator (SOI) technique. The switch device 200 includes power distribution function block 210 and a plurality of routing circuits 220-1 to 220-4.

The power distribution function block 210 has one end thereof connected to the port P1 and the other end thereof connected to the plurality of routing circuits 220-1 to 220-4. The power distribution function block 210 includes one or more variable resistor circuits 212a to 212c (also referred to as “variable resistor circuit(s) 212”) connected in series. In the example of the present drawing, the variable resistor circuits 212 have resistor elements and semiconductor switches connected in parallel, and function as a resistor of a resistance value the resistor elements have when the semiconductor switches are off, and as a transmission line in which the resistance value is substantially zero when the semiconductor switches are on. The power distribution function block 210 is configured to match impedances with circuits such as the testing circuit 10 electrically connected to the port P1 by being controlled from the connection control circuit 130 to adjust the resistance value in accordance with the number of ports among the plurality of ports P2-1 to P2-4 electrically connected to the port P1. It will be noted that the switch device 200 may not include the power distribution function block 210. In this case, the switch device 200 may have each routing circuit 220 match impedances, and thus may not have the impedance matching function.

The plurality of routing circuits 220-1 to 220-4 each switch whether to electrically connect the port P1 and each of the plurality of ports P2-1 and P2-4. In the example of the present drawing, the switch device 200 includes four routing circuits 220 in order to switch whether to electrically connect the port P1 and each of the four ports P2. Alternatively, the routing circuits 220 may include any number greater than or equal to two of routing circuits 220 in order to switch whether to electrically connect the port P1 and each of any number greater than or equal to two of ports P2.

Each routing circuit 220 has one end thereof connected to the power distribution function block 210 and the other end thereof connected to a corresponding port P2 among the plurality of ports P2-1 to P2-4. Since the plurality of routing circuits 220-1 to 220-4 have similar configurations, in the following, a configuration of the routing circuit 220-1 is shown as a representative, and the description of the routing circuits 220-2 to 220-4 is omitted except for differences.

The routing circuit 220-1 includes a through switch 222-1 (also referred to as “through switch(es) 222”), a shunt switch 224-1 (also referred to as “shunt switch(es) 224”), and at least one of variable resistor circuits 226-1a to 226-1c (also referred to as “variable resistor circuit(s) 226”). The through switches 222 have one end thereof connected to the power distribution function block 210 and the other end thereof connected to the shunt switches 224 and the variable resistor circuits 226. The through switches 222 function as a “connection switching circuit” for switching whether to electrically connect the port P1 and a corresponding port P2 among the plurality of ports P2 (the port P2-1 in the through switch 222-1).

The shunt switches 224 are connected to wirings between the port P1 and the corresponding port P2 among the plurality of ports P2 (the port P2-1 in the through switch 222-1), and the other end thereof is connected to a reference potential (also can be considered as a “ground potential”). The shunt switches 224 may be connected between a wiring between the through switch 222 and the variable resistor circuit 226-1a, and the reference potential. The shunt switches 224 function as a “ground switching circuit” for switching whether to ground a wiring between the port P1 and a corresponding port P2 among the plurality of ports P2. The routing circuit 220 may include one or more shunt switches 224. In each of the plurality of routing circuits 220, the shunt switch 224 grounds the wiring between the port P1 and a corresponding port P2 among the plurality of ports P2 when the port P1 and the corresponding port P2 among the plurality of the ports P2 are not electrically connected.

The one or more variable resistor circuits 226 are connected on the wiring between the port P1 and a corresponding port P2 among the plurality of ports P2 (the port P2-1 in the through switch 222-1). A plurality of variable resistor circuits 226 may be connected on the wiring between the port P1 and the corresponding port P2 in series. The one or more variable resistor circuits 226 make a connection resistance value variable when the port P1 and the corresponding port P2 among the plurality of ports P2 are electrically connected. Each variable resistor circuit 226 may have a configuration similar to that of the variable resistor circuit 212.

The one or more variable resistor circuits 226 are configured to match impedances with circuits such as the testing circuit 10 electrically connected to the port P1 by being controlled from the connection control circuit 130 to adjust the resistance value in accordance with the number of ports among the plurality of ports P2-1 to P2-4 electrically connected to the port P1. It will be noted that the switch device 200 may not include the one or more variable resistor circuits 226. In this case, the switch device 200 may not have the impedance matching function for adjusting the resistance value in accordance with the number of ports P2 electrically connected the port P1.

The switch device 200 described above can be considered as including the power distribution function block 210, an SP4T block 230, and a power distribution function block 240 from the functional perspective. The SP4T block 230 is configured to switch connections between the port P1 and any number or combination of the ports P2 among the plurality of ports P2. The example of the present drawing shows that the port P1 and the port P2-1 are electrically connected, and the port P1 and the three ports P2-2 to P2-4 are electrically disconnected. The power distribution function block 210 and the power distribution function block 240 are configured to adjust a resistance value between the port P1 and a port P2 corresponding to the power distribution function block 240 in accordance with the number or combination of the ports P2 connected to the port 1.

In the above, a resistance value R between the port P1 and each port P2 may be set similar to the one in Patent document 1 as an example. That is, for example, let L be the number of the ports P2 electrically connected the port P1, R₀ be a reference impedance, and M=L−1, then the resistance value R between the port P1 and each port P2 may be determined by the following equation (1):

$$R = {R}_{0} \times ( M - 1 ) / ( M + 1 ) \qquad ( 1 )$$

The resistance value R between the port P1 and the corresponding port P2 may also be set within a range of predetermined allowable error (e.g., +/−10%) with respect to the value of the above equation (1). In order to adjust the resistance value R, let Q be the number of resistors, and Rx be the minimum unit of the adjustable resistance value, then the resistance value of each variable resistor circuit 212 and each variable resistor circuit 226 may be the resistance value of i-th resistor: Rᵢ=2ⁱ⁻¹ Rₓ, where 1<=i<=Q. Here, the resistance value of each variable resistor circuit 212 may be selected from the resistance values Ri in the descending order, and the resistance value of each variable resistor circuit 226 (the resistance value when the semiconductor switches are off) may be selected from the resistance values Rᵢ in the ascending order. This allows the switch device 200 to make the resistance value R between the port P1 and each port P2 to the digital value specified in Q bits multiplied by Rₓ. It will be noted that the resistance value R between the port P1 and each port P2 may be achieved by using variable resistors other than the above one. In addition, a set of the resistance value R that can be set may be determined in accordance with a range of allowable error of the impedance matching.

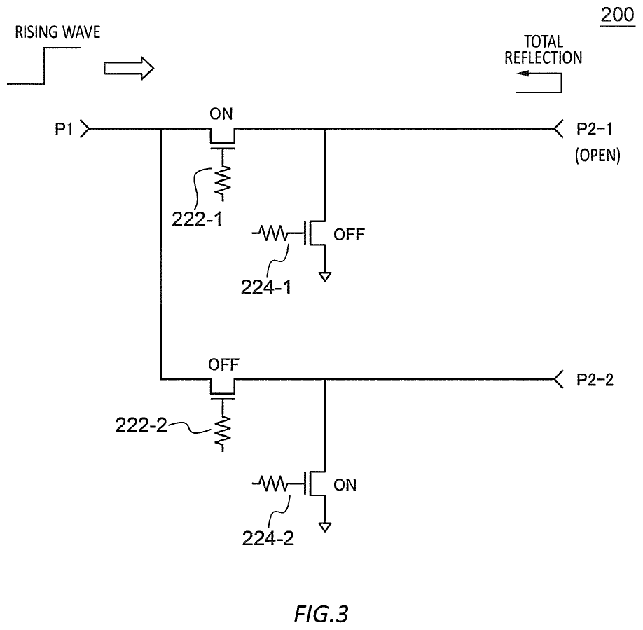

FIG. 3 illustrates a state of the switch device 200 in which the ports P1 and P2-1 are electrically connected and the ports P1 and P2-2 are electrically disconnected. The port P1 of the switch device 200 is electrically connected to the testing circuit 10, and each port P2 is electrically connected to a DUT. The through switch 222-1 and the shunt switch 224-2 turn on, and the shunt switch 224-1 and the through switch 222-2 turn off.

Here, the DUT to be supplied with the test signal has a predetermined impedance if the DUT is normal, but can become short or open with respect to a terminal due to the failure of the DUT or the like. In addition, if there is an error of a testing procedure or the like, the testing circuit 10 can unintentionally supply the port P1 with the test signal with the DUT disconnected thereto.

In the example of the present drawing, if an input from the port P1 rises when the terminal of the DUT connected to the port P2-1 is open, the rising wave is reflected totally at the open end of the DUT to be superimposed on the original input. Thus, a voltage across the part of the wiring which is conducted with the port P2-1 may rise up to a voltage that is twice of an amplitude of an output signal to be output from the port P2-1. For example, when the input from the port P1 rises from 0 V to 10 V and this signal is about to be output from the port P2-1, the wiring between the port P1 and the port P2-1 may rise up to 20 V by a reflected wave from the port P2-1. In this case, a voltage that is twice of the amplitude of the output signal (e.g., 20 V) may be applied between main terminals of the shunt switch 224-1 and the through switch 222-2 that are off. Therefore, in the configuration of the switch device 200, each of the through switches 222 and the shunt switches 224 is required to have a withstand voltage that is twice of the maximum amplitude of the output signal to be output from the ports P2.

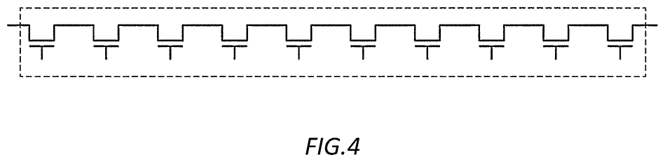

FIG. 4 illustrates an example of a configuration of a through switch 422 and a shunt switch 424 as a comparative example. As shown in connection to FIG. 3, each of the through switches 222 and the shunt switches 224 in the switch device 200 is required to have a withstand voltage that is twice of the maximum amplitude of the output signal to be output from the ports P2. In order to enhance their withstand voltage, the through switches 222 and the shunt switches 224 are achieved by the through switch 422 and the shunt switch 424 with a required number of switching devices by an FET such as a MOSFET connected in series as an example. For example, when the switching devices have a withstand voltage of 2 V, the through switch 422 and the shunt switch 424 can achieve a withstand voltage of 20 V by employing a configuration of ten switching devices connected in series. However, if the through switch 422 and the shunt switch 424 having a withstand voltage that is twice of the maximum amplitude of the output signal are used as all the through switches 222 and the shunt switches 224 in the switch device 200, problems may occur such as that the number of switching devices connected in series between the port P1 and each port P2 increases and thus on-resistances become higher or the loss characteristics of signals deteriorate, and that the size of the switch device 200 unintentionally increases.

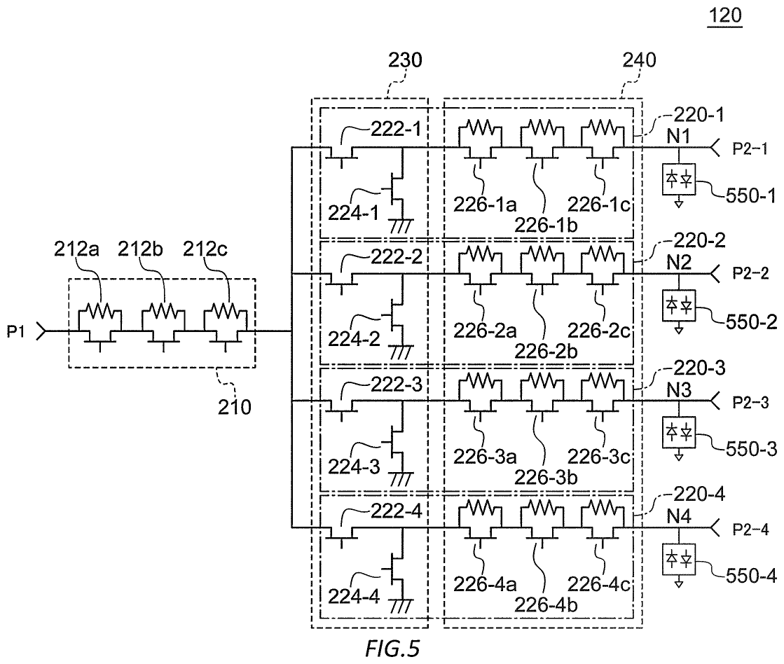

FIG. 5 illustrates an example of a circuit configuration of the switch device 120 shown in FIG. 1 according to the present embodiment. Since the switch device 120 is a modification of the switch device 200 that is a comparative example, components having a similar function and configuration have the same reference numerals and the description thereof will be omitted below.

The switch device 120 includes a plurality of clamp circuits 550-1 to 550-4 (also referred to as “clamp circuit(s) 550”) in addition to each component of the switch device 200. The plurality of clamp circuits 550 are each electrically connected between a node N on a wiring between each of the plurality of ports P2-1 to P2-4 and a corresponding routing circuit 220 among the plurality of routing circuits 220-1 to 220-4, and a reference potential (ground potential). For example, the clamp circuit 550-1 is electrically connected between a node N1 on a wiring between the port P2-1 and the routing circuit 220-1 corresponding to the clamp circuit 550-1 and the port P2-1, and the reference potential.

Each of the plurality of clamp circuits 550, even if a terminal of a DUT is open and the output signal is totally reflected at the DUT, restricts a potential difference between a corresponding node N and the ground to greater than a maximum value and less than twice the maximum value of a potential difference between the output signal to be output from the ports P2 and the ground. That is, each clamp circuit 550 sets a voltage restriction between the node N and the ground by an allowable potential difference that is the maximum value of the potential difference between the output signal to be output from the ports P2 and the ground multiplied by a predetermined multiplying factor greater than one and less than two. Each clamp circuit 550 may use a multiplying factor less than 1.6 or may use a multiplying factor less than 1.4 or a multiplying factor less than 1.2 as such predetermined multiplying factor. Each clamp circuit 550, in order to meet required specifications such as, for example, suppressing a insertion loss characteristics, meeting the conditions such as a 1 dB compression point or a third-order intercept point (IP3), may use a multiplying factor within the range in which the upper limit and the lower limit are determined such as, for example, a multiplying factor of greater than 1.4 and less than 1.6 as such predetermined multiplying factor.

It will be noted that each of the plurality of clamp circuits 550 may be electrically connected between a node on a wiring between a corresponding port P2 among the plurality of ports P2-1 to P2-4 and a through switch 222 of a corresponding routing circuit 220 among the plurality of routing circuits 220-1 to 220-4, and a reference potential. For example, the clamp circuit 550-1 may be electrically connected between a node between a corresponding through switch 222-1 and a variable resistor circuit 226-1a, and a reference potential.

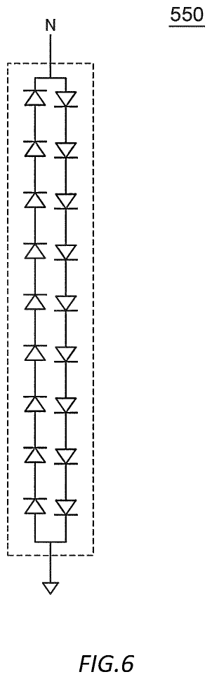

FIG. 6 illustrates an example of a circuit configuration of the clamp circuit 550 according to the present embodiment. Each clamp circuit 550 has a plurality of first diodes that are forward connected in series between the corresponding node N and the reference potential. In the present drawing, a plurality of diodes on the right side of the drawing are forward connected in series with the anodes on the node N side and the cathodes on the ground side. The plurality of diodes thus connected can restrict the voltage across the node N side to a value of (the number of diodes)×(the forward voltage across one diode) or less. That is, for example, the clamp circuit 550 can restrict such that the voltage across the node N does not exceed, e.g., 14 V.

Each clamp circuit 550 may have a plurality of second diodes that are backward connected in series between the corresponding node and the reference potential. In the present drawing, a plurality of diodes on the right side of the drawing are backward connected in series with the anodes on the ground side and the cathodes on the node N side. The plurality of diodes thus connected can restrict the voltage across the node N side to a value of −(the number of diodes)×(the forward voltage across one diode) or more. That is, for example, the clamp circuit 550 can restrict such that the voltage across the node N does not fall below, e.g., −14 V. It will be noted that the clamp circuit 550, instead of the above circuit configuration, may be achieved by using, e.g., a Zener diode, or may be achieved by using any other voltage restricting means.

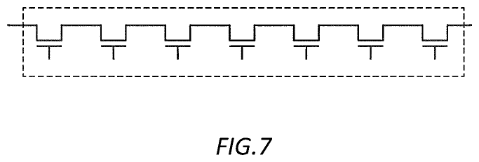

FIG. 7 illustrates an example of a circuit configuration of the through switches 222 and the shunt switches 224 shown in the FIG. 5 according to the present embodiment. As shown in connection to FIG. 6, the clamp circuit 550 restricts the voltage across the node N to less than twice of the maximum amplitude of the output signal to be output from the ports P2. Therefore, in the configuration of FIG. 5, the through switches 222 and the shunt switches 224 in the switch device 120 only have to have a withstand voltage less than twice of the maximum amplitude of the output signal corresponding to the voltage restricted by the clamp circuit 550. For example, assuming that the maximum amplitude of the output signal to be output from the ports P2 is 10 V and the clamp circuit 550 sets a voltage restriction of 14 V, then each through switch 220 and each shunt switch 224 only have to have a withstand voltage of 14 V, and do not have to have a withstand voltage up to 20 V, which is twice of 10 V.

For example when the switching devices have a withstand voltage of 2 V, then ten switching devices are required to be connected in series in order to allow a withstand voltage of 20 V (see FIG. 4). Compared to this, each through switch 222 and each shunt switch 224 only have to have a withstand voltage of 14 V, so it is only necessary to have seven switching devices connected in series. That is, each through switch 222 and each shunt switch 224 may have the same or almost the same withstand voltage as the maximum voltage allowed by the clamp circuit 550, and thus may have a withstand voltage including some margin with respect to the maximum voltage allowed by the clamp circuit 550. Such margin may be included within the range in which, for example, the lower limit is 1%, 3%, 5%, or 10% or more of the maximum voltage, the upper limit is 5%, 10%, 15%, or 20% or less of the maximum voltage, and which may be determined by any combination of the upper limit and the lower limit as long as the upper limit is greater than the lower limit.

Therefore, the switch device 120 including the clamp circuit 550 can use the through switches 222 and the shunt switches 224 that have relatively less withstand voltage such as ones in which fewer switching devices are connected in series, compared to the switch device 200 not including the clamp circuit 550. This allows for the switch device 120 to decrease on-resistances between the port P1 and each port P2 and improve the loss characteristics. In addition, the switch device 120 can decrease the number of switching devices included in the through switches 222 and the shunt switches 224, decreasing the size of the switch device 120.

It will be noted that the through switches 222 and the shunt switches 224 may have a configuration other than the above one. Even if switches such as the through switches 222 and the shunt switches 224 took some other configuration, they would tend to have a higher on-resistance as they have a higher withstand voltage in the similar configuration such as one employing same materials, exacerbate the loss characteristics, or increase in size. Therefore, the switch device 120 can obtain the above effect even if the through switches 222 and the shunt switches 224 having a configuration other than the above one are employed.

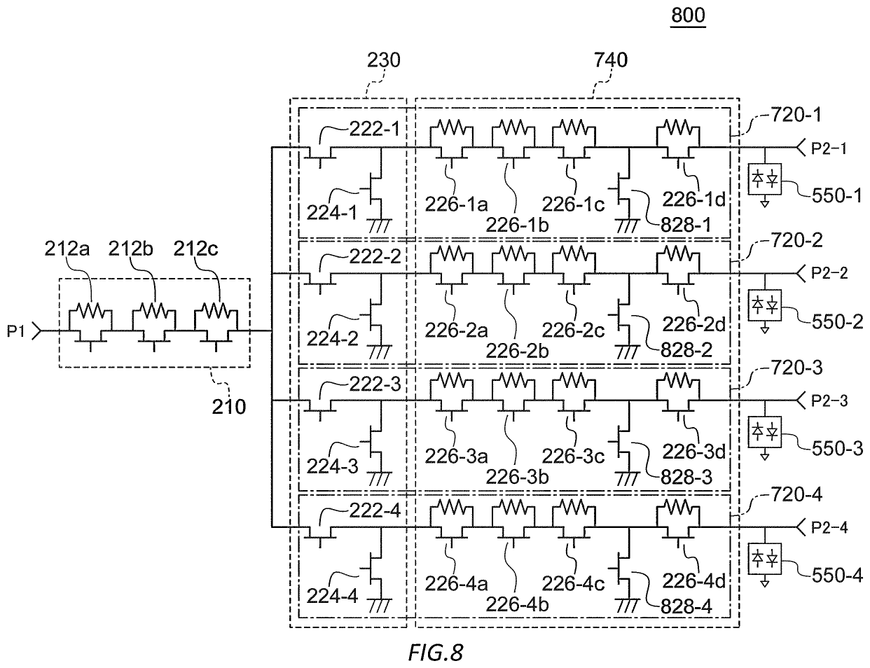

FIG. 8 illustrates an example of a circuit configuration of a switch device 800 according to a modification of the present embodiment. Since the switch device 800 is a modification of the switch device 120 shown in FIG. 5, components having a similar function and configuration have the same reference numerals and the description thereof will be omitted below. The switch device 800 includes a plurality of routing circuits 720-1 to 720-4 (also referred to as “routing circuit(s) 720”) instead of the plurality of routing circuits 220-1 to 220-4. With this change, the power distribution function block 240 in FIG. 5 is substituted with a power distribution function block 740. The routing circuit 720-1 as a representative of the routing circuits 720-1 to 720-4 will be described below.

The routing circuit 720-1 is different from the routing circuit 220-1 in that the routing circuit 720-1 has a variable resistor circuit 226-1d in addition to the plurality of variable resistor circuits 226-1a to 226-1c, and that the routing circuit 720-1 has a plurality of ground switching circuits by having a shunt switch 828-1 as a ground switching circuit in addition to the shunt switch 224-1 as the ground switching circuit. In each of the plurality of routing circuits 720, all ground switching circuits (the shunt switches 224 and 828) are connected nearer to the port P1 than the variable resistor circuit 226 that is connected nearest to the ports P2 among the plurality of variable resistor circuits 226 in a wiring between the port P1 and a corresponding port P2 among the plurality of ports P2-1 to P2-4. For example, in the routing circuit 720-1, all ground switching circuits (the shunt switches 224-1 and 828-1) are connected nearer to the port P1 than the variable resistor circuit 226-1d, which is connected nearest to the port P2-1 in the wiring between the port P1 and the port P2-1. In other words, at least one variable resistor circuit 226 (variable resistor circuit 226-1d) is arranged nearer to the port P2-1 than all ground switching circuits (the shunt switches 224-1 and 828-1).

When the connection control circuit 130 electrically disconnects between the ports P1 and P2-1, it may turn the through switch 222-1 off and the shunt switches 224-1 and 828-1 on, and determine a resistance value of the variable resistor circuit 226-1d to be matched or substantially matched with the impedance of the DUT connected to the port P2-1,

Accordingly, when the switch device 800 electrically disconnects between the ports P1 and P2-1, it can cause the variable resistor circuit 226-1d to function as a terminal resistor, and match the impedance of the circuit on the switch device 800 side with the impedance of the circuit on the DUT side. Therefore, the switch device 800 can prevent circuits in the DUT from failing due to high voltage generated by total reflection of the signal output from the DUT to the port P2-1.

It will be noted that when the connection control circuit 130 electrically connects between the ports P1 and P2-1, it may turn the through switch 222-1 off and the shunt switches 224-1 and 828-1 on, and set the resistance value of the variable resistor circuit 226-1d to zero or a minimum value. This allows for the switch device 800 to use the variable resistor circuit 226-1d as just a wiring when the switch device 800 electrically connects between the ports P1 and P2-1.

In the embodiments and modifications described above, the switch device 200, the switch device 120, and the switch device 800 are used as a part of the connecting device 20 of the testing device 1. Alternatively, the switch device 200, the switch device 120, and the switch device 800 may be used in any devices that establish one-to-many connection.

While the embodiments of the present invention have been described, the technical scope of the invention is not limited to the above described embodiments. It is apparent to persons skilled in the art that various alterations or improvements can be added to the above-described embodiments. It is also apparent from the claims that the embodiments added with such alterations or improvements can be included in the technical scope of the present invention.

Note that the operations, procedures, steps, and stages of each process performed by a device, system, program, and method shown in the claims, specification, or drawings can be performed in any order as long as the order is not indicated by “prior to,” “before,” or the like and as long as the output from a previous process is not used in a later process. Even if the operation flow is described by using phrases such as “first” or “next” in the claims, specification, or drawings, it does not necessarily mean that the process must be performed in this order.

### EXPLANATION OF REFERENCES

1: testing device;
10: testing circuit;
20: connecting device;
100a to 100b: switch device;
110a to 110b: switch device;
120a to 120b: switch device;
130: connection control circuit;
200: switch device;
210: power distribution function block;
212a to 212c: variable resistor circuit;
220-1 to 220-4: routing circuit;
222-1 to 221-4: through switch;
224-1 to 224-4: shunt switch;
226-1a to 226-4d: variable resistor circuit;
230: SP4T block;
240: power distribution function block;
422: through switch;
424: shunt switch;
550-1 to 550-4: clamp circuit;
720-1 to 720-4: routing circuit;
740: power distribution function block;
800: switch device;
828-1 to 828-4: shunt switch.

What is claimed is:

1. A switch device comprising:
a plurality of routing circuits each configured to switch whether to electrically connect between a first port and each of a plurality of second ports; and
a plurality of clamp circuits,
wherein each of the plurality of routing circuits comprises:
a connection switching circuit configured to switch whether to electrically connect between the first port and a corresponding second port among the plurality of second ports; and
at least one ground switching circuit configured to switch whether to ground a wiring between the first port and the corresponding second port among the plurality of second ports,
and wherein each of the plurality of clamp circuits is electrically connected between a node on a wiring between the corresponding second port among the plurality of second ports and the connection switching circuit of a corresponding routing circuit among the plurality of routing circuits, and a reference potential.

2. The switch device according to claim 1,
wherein each of the plurality of clamp circuits is electrically connected between nodes on wirings between each of the plurality of second ports and the corresponding routing circuit among the plurality of routing circuits, and a reference potential.

3. The switch device according to claim 2,
wherein the at least one ground switching circuit of each of the plurality of routing circuits is configured to ground the wiring between the first port and the corresponding second port among the plurality of second ports when the first port and the corresponding second port among the plurality of second ports are not electrically connected.

4. The switch device according to claim 3,
wherein each of the plurality of clamp circuits is configured to restrict a potential difference between the corresponding node and the ground to greater than a maximum value and less than twice the maximum value of a potential difference between an output signal to be output from the second ports and the ground.

5. The switch device according to claim 1,
wherein each of the plurality of clamp circuits is configured to restrict a potential difference between the corresponding node and the ground to greater than a maximum value and less than twice the maximum value of a potential difference between an output signal to be output from the second ports and the ground.

6. The switch device according to claim 4,
wherein each of the plurality of clamp circuits comprises
a plurality of first diodes that are forward connected in series between the corresponding node and the reference potential.

7. The switch device according to claim 5,
wherein each of the plurality of clamp circuits comprises
a plurality of first diodes that are forward connected in series between the corresponding node and the reference potential.

8. The switch device according to claim 6,
wherein each of the plurality of clamp circuits comprises
a plurality of second diodes that are backward connected in series between the corresponding node and the reference potential.

9. The switch device according to claim 7,
wherein each of the plurality of clamp circuits comprises
a plurality of second diodes that are backward connected in series between the corresponding node and the reference potential.

10. The switch device according to claim 1,
wherein each of the plurality of routing circuits comprises
at least one variable resistor circuit configured to make a connection resistance value variable when the first port and the corresponding second port among the plurality of second ports are electrically connected.

11. The switch device according to claim 10,
wherein, in each of the plurality of routing circuits, all ground switching circuits among the at least one ground switching circuit are connected nearer to the first port than a variable resistor circuit that is connected nearest to the second ports among the at least one variable resistor circuit in the wiring between the first port and the corresponding second port among the plurality of second ports.

12. The switch device according to claim 1,
wherein the plurality of second ports are connected to one or more devices under test, and
the first port is connected to a testing circuit configured to test the one or more devices under test.

13. The switch device according to claim 4,
wherein the plurality of second ports are connected to one or more devices under test, and
the first port is connected to a testing circuit configured to test the one or more devices under test.

14. The switch device according to claim 5,
wherein the plurality of second ports are connected to one or more devices under test, and
the first port is connected to a testing circuit configured to test the one or more devices under test.

15. A testing device comprising:
the switch device according to claim 12; and
the testing circuit.

16. A testing device comprising:
the switch device according to claim 14; and
the testing circuit.
